(19) United States
(12) Patent Application Publication
(10) Pub. No.: US 2003/0014864 A1
(43) Pub. Date: Jan. 23, 2003

(54) Process for mass prodcution of plates for holding connection pins of electronic components

(76) Inventors: Yves Gazelot, Brie Comte Robert (FR); Thierry Robin, Chevry Cossigny (FR)

Correspondence Address: PERMAN & GREEN, 425 POST ROAD, FAIRFIELD, CT, 06824, US

(21) Appl. No.: 10/177,494

(22) Filed: Jun. 20, 2002

(30) Foreign Application Priority Data
Jun. 22, 2001 (FR) 01/08275

(51) Int. Cl. H05K 3/30; H05K 3/02

(52) U.S. Cl. 29/852; 29/847; 29/832

(57) ABSTRACT

In order to mass produce plates for holding connection pins of an electronic component in a predefined configuration, used to facilitate the mounting of the component on a printed circuit board, this process consists of introducing a board (11) of large dimensions into a numerically-controlled machine tool, operating the machine tool in order to create in board (11) perforations (12) whose diameter corresponds to that of the pins of the component, and to operate the machine tool in order to make precutting lines (13, 14) in board (11), so as to precut a plurality of plates (21) in the board, the precutting lines being distributed over the board so that each plate has perforations (12) having the predefined configuration.

The present invention concerns a process for manufacture of disks or plates for holding connection pins of electronic components.

Such a disk is used for mounting an electronic component on a printed circuit board. Such a mounting is realized by engaging the connection pins of the component in holes made for this purpose in the printed circuit board. The connection pins of the component are then soldered onto metal contacts formed on the surface of the printed circuit board, around holes in which they are engaged.

This disk is provided with a plurality of holes in which the connection pins of the component are engaged to hold the latter in a precise configuration, corresponding to that of holes provided in the printed circuit board for mounting and connection of the component. Such a disk is particularly useful in the case where the connection pins of the component must be kept long or are bent to a right angle, particularly for adapting the configuration of the pins of the component to that of the holes made in the printed circuit.

At the present time, these disks are made by molding and therefore by means of molds. Now, such molds require long manufacturing times, of the order of several months, and are expensive.

Since the number of pins varies from one component to another, and the distribution of the latter depends on the type of component and its layout on the printed circuit board, it is necessary to create a mold for each type of component and each application of the component. As a result, costs and development times for new printed circuit boards become prohibitive. This solution is also inapplicable to component groups that bring together a large number of components having different pin distributions.

Moreover, these disks have a poor temperature resistance, and the molding technique employed leads to imprecisions with regard to the respective positions of the holes which must then be created with a larger diameter. As a result of this, the use of holding sleeves is necessary which are engaged beforehand on the pins, in order to hold the disk on the connection pins at the time of positioning the component on the printed circuit board.

The object of the present invention is to eliminate these disadvantages. This object is attained by the implementation of a manufacturing process for plates for holding connection pins of an electronic component in a predefined configuration, to facilitate the mounting of the component on a printed circuit board, these plates having perforations whose distribution corresponds to said predefined configuration, and whose diameter is greater than or equal to that of the connection pins, characterized in that it comprises the steps consisting of:

introducing a board of large dimensions into a numerically-controlled machine tool,

operating the numerically-controlled machine tool to create perforations whose diameter corresponds to that of the pins in the board,

operating the machine tool to create precutting lines in the board, so as to precut a plurality of plates in the board, the precutting lines being distributed over the board so that each plate has perforations whose distribution on the plate corresponds to said predefined configuration.

In this manner, the process according to the invention permits inexpensively manufacturing large quantities of plates provided with perforations whose configuration and diameter-are created with the very great precision of numerically-controlled machine tools. The chamfers which were provided to facilitate the positioning of the pins of the components in the perforations are therefore not necessary.

Advantageously, the process according to the invention also comprises a step of separating the precut plates from the board.

According to one particular point of the invention, this process also comprises the operation of the machine tool to create at least two groups of precutting parallel lines, each precutting line of one group crossing the precutting lines of the other groups of precutting lines.

Advantageously, each precutting line of a group crosses the precutting lines of the other group at a right angle.

According to another particular point of the invention, this process also comprises the operation of the machine tool to create perforations of greater diameter than that of the perforations with predetermined configuration, centered on the intersection points of the precutting lines.

According to another particular point of the invention, this process also comprises the operation of the machine tool to create three groups of parallel precutting lines, each precutting line of a group crossing the precutting lines of the two other groups of lines.

Preferably, the machine tool is operated so that said precutting lines are created on both sides of the board and at the same places, to facilitate the separation of the plates from the board.

Advantageously, the machine tool is operated so that the plates of the board have different dimensions and configurations of perforations from one plate to another.

Preferably, said board is a printed circuit board.

The machine tool is advantageously controlled by a program for creating said perforations and said precutting lines.

One preferred mode of embodiment of the invention will be described below, by way of nonlimiting example, with reference to the attached drawings in which:

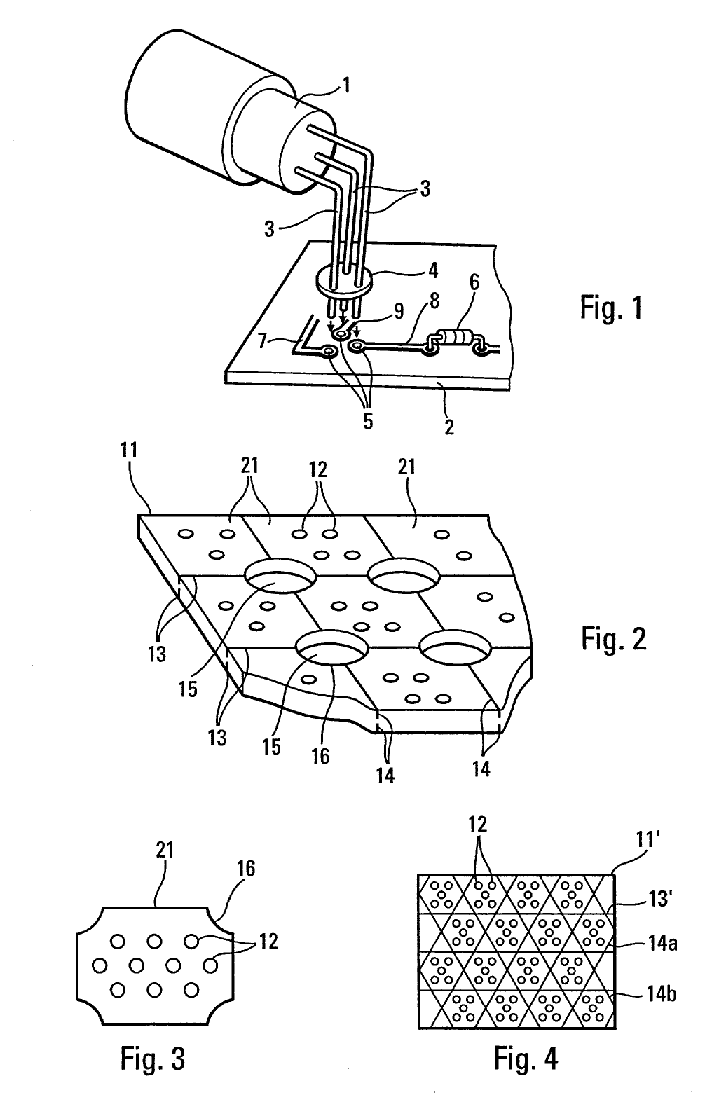

FIG. 1 represents a perspective view of an electronic component mounted on a printed circuit board shown in partial view, the connection pins of the component being held in a certain distribution by a disk obtained by a process of the prior art;

FIG. 2 shows a partial and perspective view of a board machined according to the invention to create plates for maintaining the distribution of connection pins for electronic components;

FIG. 3 shows in top view a plate obtained by the process according to the invention.

FIG. 1 shows an electronic component 1 mounted on a printed circuit board 2. Component 1 has connection pins 3 designed to be engaged in holes 5 formed in printed circuit board 2 for the attachment and connection of the component. Holes 5 cross metal contacts made at conductive tracks 7, 8, 9 and onto which the pins of the component are soldered.

During mounting of a component on a printed circuit board, it is sometimes necessary for connection pins 3 of the component to be held in a precise configuration corresponding to that of holes 5 made in printed circuit board 2. For this purpose, the connection pins are engaged beforehand in respective holes made in a disk 4, the configuration or distribution of the holes in the disk corresponding to that of holes 5 formed in plate 2.

As shown in FIG. 1, connection pins 3 of component 1 can be bent beforehand, for example, at a right angle, to adapt their distribution to connection holes 5 formed in printed circuit board 2.

In FIG. 2, the manufacture of such disks or plates conforming to the process according to the invention uses a machine tool with numerical control which is programmed to create in a board of relatively large dimensions, several plates 21 for holding connection pins for electronic components in predefined configurations. The machine tool is programmed to create holes 12 for the insertion of the pins of components and precutting lines 13, 14 for defining plates 21, each plate being furnished with holes whose distribution corresponds to the configuration of the connection pins of a given Component for a given printed circuit board. Such a programming notably consists of introducing the precise coordinates of each precutting line 13, 14.

The diameter of the holes to be created corresponds to that of the drills available to the machine tool, which also has available a circular saw to make the precutting lines.

Due to the great flexibility of use of such a machine tool, it is thus possible by a simple programming step, to manufacture plates designed for any component whatever regardless of application.

The process according to the invention thus advantageously exploits the great precision and great flexibility offered by numerically-controlled machines whose programming is considerably more rapid than the creation of a mold.

Moreover, current machine tools are capable of making holes 12 and precutting lines 13, 14 with a very great precision. It results from this that holes 12 of plates 21 thus obtained can be entirely cylindrical and can be exactly adapted to the diameter of the connection pins of the components, without rendering the insertion of the component pins in holes 12 more difficult. In such a manner, a plate 21 can be made so as to be exactly adapted to a precise configuration of connection pins, so as to be engaged and held without risk of slipping on the connection pins of the component.

In contrast, the holes formed in the molded disks of the prior art must be slightly flared and of greater diameter to compensate for the imprecisions of molding notably due to the imperfections of the mold.

Due to the flexibility of numerically-controlled machines, the number, the distribution and the diameter of holes 12 per plate 21 of the same board 11, as well as the size of the plates, can be different from one plate 21 to another. Thus, in FIG. 2, board 11 has a row of plates 21 with two holes 12, a row of plates with four holes and a row of plates with three holes in order to be adapted for components with two, four and three connection pins, respectively.

Precutting lines 13, 14 are advantageously made-up of at least two groups of parallel lines. In the case of two groups of parallel precutting lines, the lines of both groups can be perpendicular to one another. In this case, plates 21 obtained are in rectangular form. As shown in FIG. 4, one can also provide three groups of precutting parallel lines 13′, 14a, 14b, to form plates 21′ of hexagonal shape, or more, to form plates of polygonal shape.

A large number of plates 21 can thus be made from a single board 11.

In the case of rectangular plates, holes of greater diameter than holes 12 for the passage of component pins can be provided, centered on the intersections between the precutting lines of the two groups, so as to reduce the size of the plates, in particular to remove the zones of the plates free of holes 12 for the passage of connection pins. FIG. 3 shows a plate 21 of rectangular shape, provided with ten holes 12 and whose corner zones 16 have been removed by means of the formation of holes 15 at the intersection points of cutting lines 13, 14.

Precutting lines 13, 14 are preferably made on both sides of board 11, at the same places and over a fraction of the thickness of the board, to facilitate the final separation of plates 21 from one another.

Plates 21 are advantageously made in a board 11 of epoxy resin, i.e., in the same material as a printed circuit board. Of course, in order to avoid the risks of short circuit between the connection pins, the metal plating of the board must be removed at least in the vicinity of holes 12. As a result, the temperature resistance of plates 21 thus obtained is equivalent to that of the printed circuit on which the component is mounted.

Holes 12 have, for example, a diameter of 0.7 mm for a thickness of board 11 of 0.8 mm.

1. A manufacturing process for plates for holding connection pins (3) of an electronic component (1) in a predefined configuration in order to facilitate the mounting of the component on a printed circuit board, these plates (21) having perforations (12) whose distribution corresponds to said predefined configuration, and whose diameter is greater than or equal to that of the connection pins,
characterized in that it comprises the steps consisting of:
introducing a board (11) of large dimensions into a machine tool with numerical control,
operating the machine tool to create in board (11) perforations (12) whose diameter corresponds to that of pins (3),
operating the machine tool to create precutting lines (13, 14) in the board, so as to precut a plurality of plates (21) in the board, the precutting lines being distributed over the board so that each plate has perforations (12) whose distribution on the plate corresponds to said predefined configuration.

2. The manufacturing process according to claim 1,
further characterized in that it comprises a step of separation of precut plates (21) from board (11).

3. The manufacturing process according to claim 1 or 2, further characterized in that it comprises the operation of the machine tool to create at least two groups (13, 14) of parallel precutting lines, each precutting line of a group crossing the precutting lines of the other groups of precutting lines.

4. The manufacturing process according to one of claims 1 to 3, further characterized in that it comprises the operation of the machine tool to create two groups (13, 14) of parallel precutting lines, each precutting line of a group crossing the precutting lines of the other group at right angles.

5. The manufacturing process according to claims 1 to 3, further characterized in that it comprises the control of the machine tool to create three groups (13′, 14a, 14b) of parallel precutting lines, each precutting line of a group crossing the precutting lines of the other two groups of lines.

6. The manufacturing process according to one of claims 3 to 5, further characterized in that it comprises the operation of the machine tool to create perforations (15) of larger diameter than perforations (12) with predetermined configuration, centered on the intersection points of precutting lines (13, 14).

7. The manufacturing process according to one of claims 1 to 6, further characterized in that it comprises the operation of the machine tool so that said precutting lines (13, 14) are made on both sides of board (11) and at the same places, in order to facilitate the separation of plates (21) from the board.

8. The manufacturing process according to one of claims 1 to 7, further characterized in that it comprises the operation of the machine tool so that plates (21) of board (11) have different dimensions and configurations of perforations (12) from one plate to the other.

9. The manufacturing process according to one of claims 1 to 8, further characterized in that said board (11) is a printed circuit board.

10. The manufacturing process according to one of claims 1 to 9, further characterized in that the machine tool is controlled by a program to create said perforations (12, 15) and said precutting lines (13, 14).
